(19) United States
(12) Patent Application Publication
(10) Pub. No.: US 2024/0305213 A1
(43) Pub. Date: Sep. 12, 2024

(54) POWER CONVERTER AND DRIVE DEVICE

(71) Applicant: TOYOTA JIDOSHA KABUSHIKI KAISHA, Aichi (JP)

(72) Inventor: Keisuke SAWAZAKI, Nisshin-shi (JP)

(21) Appl. No.: 18/587,957

(22) Filed: Feb. 27, 2024

(30) Foreign Application Priority Data
Mar. 10, 2023 (JP) 2023-037957

(51) Int. Cl. H02M 7/00; H02K 11/33; H05K 7/20

(52) U.S. Cl. CPC H02M 7/003; H02K 11/33; H05K 7/20927

(57) ABSTRACT

A power converter disclosed herein may include; a power module comprising at least one power semiconductor element; a metal plate being in thermal connection with the at least one power semiconductor element, and a flow path defining member including a plastic material and defining a coolant flow path together with the metal plate. A coolant may flow through the coolant flow path, and the flow path defining member may be integrated into the metal plate.

### REFERENCE TO RELATED APPLICATIONS

This application claims priority from Japanese Patent Application No. 2023-037957 filed on Mar. 10, 2023, the entire content of which is incorporated herein by reference.

### TECHNICAL FIELD

The technique disclosed herein relates to a lightweight power converter and a lightweight drive device.

### BACKGROUND

This type of power converter includes a power module as an inverter that supplies power to a motor to drive the same. The power converter also includes a metallic plate, such as a heat sink, that is in thermal connection with the inverter to cool the inverter, and a coolant flow path that supplies a coolant to this metallic plate (Japanese Patent Application Publication No. 2013-104581). Japanese Patent Application Publication No. 2013-104581 describes defining a coolant flow path by joining a lid to a coolant case within which a coolant can flow. Furthermore, Japanese Patent Application Publication No. 2013-104581 describes integrating a base plate on which an inverter is mounted with this lid.

### SUMMARY

In a cooling structure of an inverter, from the viewpoint of cooling efficiency by the coolant, both a coolant case and a lid are made of metal. Further weight reduction of a power converter and a drive device is desired.

This disclosure provides a technique that can further reduce weights of a power converter and a drive device.

A power converter disclosed herein may comprise: a power module comprising at least one power semiconductor element; a metal plate being in thermal connection with the at least one power semiconductor element, and a flow path defining member including a plastic material and defining a coolant flow path together with the metal plate. A coolant may flow through the coolant flow path. The flow path defining member may be integrated into the metal plate.

According to this power converter, the coolant flow path is constituted of metal and plastic, thus its weight is thereby reduced. In addition, since the flow path defining member is integrated into the metal plate, the structure of the coolant flow path can be simplified.

A method of producing a power converter comprising a power module disclosed herein may comprise: preparing an assembly base of the power module by integrally molding a flow path defining member including a plastic material into a metal plate to be thermally connected with the power module, the flow path defining member defining a coolant path for a coolant together with the metal plate. The method may further comprise assembling the power module into the assembly base. According to this production method, the assembly base which contributes to weight reduction can be efficiently manufactured.

A drive device disclosed herein may comprise the power converter disclosed herein and a motor configured to be driven by power supplied through the power converter. According to this drive device, a lightweight drive device is provided.

### BRIEF DESCRIPTION OF THE DRAWINGS

FIG. 1 illustrates an example of a vehicle including a drive device.

FIG. 2 illustrates a cross-sectional view of an example of a power converter included in the drive device.

FIG. 3 illustrates a cross-sectional view taken along III-III line in FIG. 2, viewed in an arrow direction.

FIG. 4 illustrates an enlarged view of an area in IV frame in FIG. 2.

FIG. 5 illustrates an example of production processes of the power converter.

### EMBODIMENT

A power converter disclosed herein may comprise; a power module comprising at least one power semiconductor element; a metal plate being in thermal connection with the at least one power semiconductor element, and a flow path defining member including a plastic material and defining a coolant flow path together with the metal plate, wherein a coolant may flow through the coolant flow path, and the flow path defining member may be integrated into the metal plate.

In one embodiment of the present disclosure, the flow path defining member may be integrated into the metal plate by holding an end of an outer edge of the metal plate. By configuring as such, integration of the metal plate and the channel forming member are ensured.

In one embodiment of the present disclosure, the flow path defining member may be integrated into the metal plate by insert molding. By configuring as such, the flow path defining member can simply and tightly be integrated into the metal plate.

In one embodiment of the present disclosure, the flow path defining member may comprise a sidewall portion surrounding the metal plate along the outer edge of the metal plate and defining a recess defined by the metal plate and the sidewall portion. By configuring as such, the coolant can simply and effectively be supplied to the metal plate.

In one embodiment of the present disclosure, the power converter may further comprise a cover member including a plastic material and closing an opening of the recess part. By the cover member also including the plastic material, the weight is further reduced.

The various embodiments of the power converter described above are also applied to a method of producing a power converter comprising a power module, which is an embodiment of the present disclosure. The various embodiments of the power converter described above are also applied to a drive device, which is an embodiment of the present disclosure.

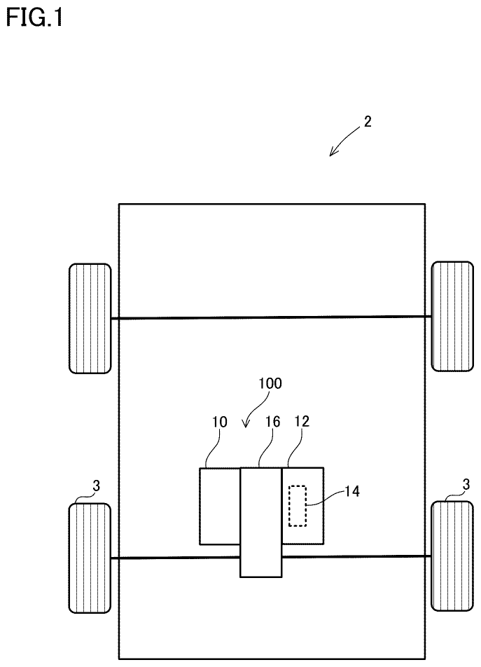

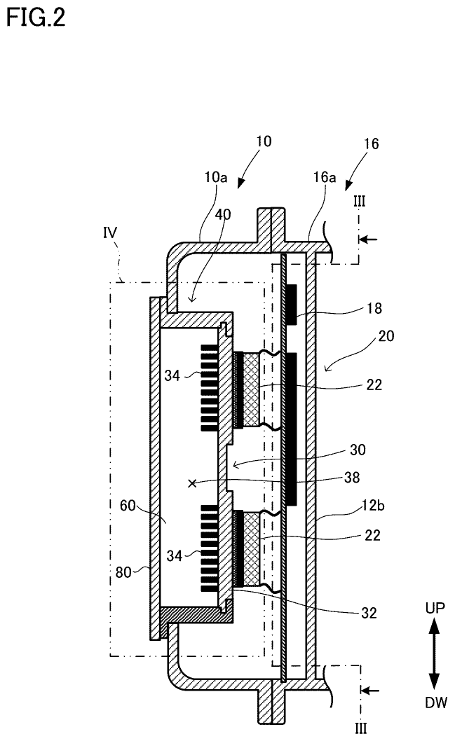

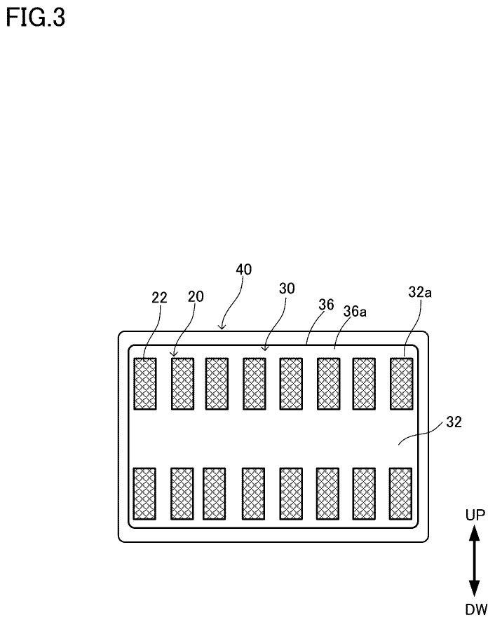

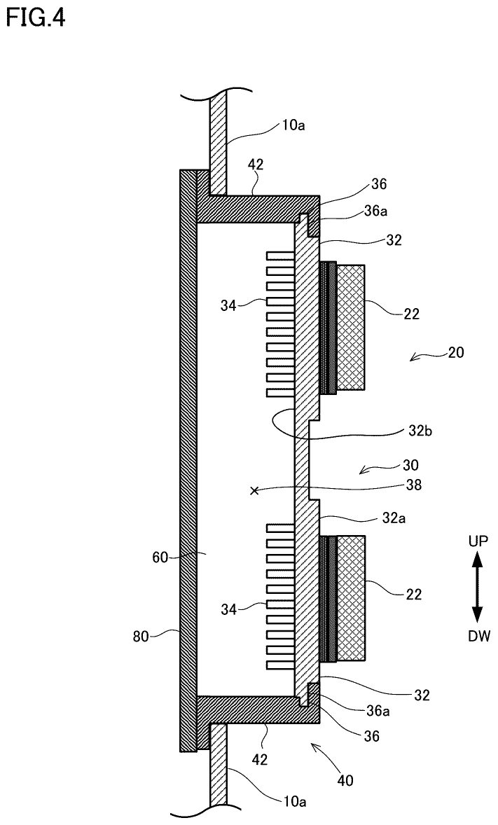

Hereinafter, a power converter and a drive device of a vehicle disclosed herein will be described with reference to the figures. FIG. 1 illustrates an example of a vehicle including a drive device disclosed herein, FIG. 2 illustrates an example of a power converter included the drive device, FIG. 3 illustrates a plan view of a part of the power converter, and FIG. 4 shows the power module, a coolant flow path of the power converter and their vicinity. In FIGS. 2 to 4, upward and downward directions with respect to the vehicle are indicated as UP and DW, respectively.

A drive device 100 illustrated in FIG. 1 is, for example, but not particularly limited to, a drive device for a vehicle 2 and is an electric drive module in which an inverter unit 10, a motor unit 12, a gear unit 16, and the like, are incorporated. The drive device 100 is configured to rotate drive wheels 3 of the vehicle 2. The vehicle 2 includes a vehicle that uses a motor to drive the axle. Examples thereof include BEVs (battery electric vehicles), HEVs (hybrid electric vehicles), PHEVs (plug-in hybrid electric vehicles), and FCVs (fuel cell vehicles).

As illustrated in FIGS. 1 and 2, the drive device 100 includes an inverter unit 10, a gear unit 16, and a motor unit 12 with these units arranged along a width direction of the vehicle 2. The gear unit 16 houses a gear in a housing 16a. The gear unit 16 is isolated from the inverter unit 10 by an isolation wall 16b. The motor unit 12 houses a motor 14 within its housing 12a. The motor 14 is electrically connected to the inverter unit 10 by a busbar (not shown).

As illustrated in FIG. 2, the inverter unit 10 is arranged adjacent to the gear unit 16. The inverter unit 10 includes a power module 20, a heat sink 30, and a flow path casing 40 inside a unit casing 10a made of aluminum or other metal. The unit casing 10a may house electrical equipment 18 therein, such as a control circuit board that controls the power module 20. The inverter unit 10 is an example of the power converter disclosed herein. An aspect of the power converter is not particularly limited. The power converter only needs to include the power module 20, the heat sink 30, and the flow path casing 40, and be capable of defining the coolant flow path, and may not be combined with other unit(s) or component(s).

The power module 20 is not particularly limited and can employ a known configuration so that it functions as an inverter. For example, as shown in FIG. 3, the power module 20 is configured as a module including a plurality of power cards 22 obtained by unitizing a plurality of power semiconductor devices such as discrete devices. The power cards 22 are assembled in a predetermined arrangement onto the heat sink 30.

The heat sink 30 holds the power module 20 and cools the power module 20. The heat sink 30 as a whole has for example a rectangular plate shape as shown in FIG. 3, and is formed of metal such as aluminum. The heat sink 30 is an example of the metal plate disclosed herein.

As shown in FIGS. 3 and 4, the heat sink 30 includes a flat plate 32 on which the power module 20 is mounted with the power module 20 arranged planarly. The power cards 22 are assembled onto a surface 32a of the plate 32 such that the power cards 22 are assembled in a predetermined arrangement and thus form the power module 20 as a whole. The connection between the power cards 22 and the plate 32 is not limited as long as the power cards 22 and the plate 32 are connected such that they can transfer heat, i.e., they are in thermal connection. For example, the power cards 22 and the plate 32 may be in direct contact, or grease with high thermal conductivity may be interposed between the power cards 22 and the plate 32. As long as the power cards 22 and the plate 32 are in thermal connection, a thin sheet material that does not significantly affect the thermal conductivity may be interposed between the power cards 22 and the plate 32. Each of the power cards 22 is, for example, but not particularly limited to, mounted via a plastic plate on a silver paste applied to the surface 32a of the plate 32 of the heat sink 30.

As shown in FIGS. 2 and 4, the heat sink 30 includes multiple fins 34 on a surface 32b opposite to the surface 32a. The fins 34 are included to increase a contact area with the coolant. The fins 34 extend a predetermined length from the surface 32b to the coolant flow path 60. The fins 34 are included in a predetermined arrangement in accordance with the arrangement of the power cards 22, a direction of coolant flow, and the like. A cross-sectional shape of each of the fins 34 is not particularly limited, and various known shapes can be adopted. The fins 34 are formed at the same time when the heat sink 30 is manufactured by casting, or are formed by known methods such as cutting after casting. When used herein, the coolant refers to a liquid coolant such as cooling water for cooling the inverter unit 10 or the power module 20.

The flow path casing 40 is integrated into the heat sink 30 along the outer edge 36 of the heat sink 30. The flow path casing 40, together with the heat sink 30, defines a coolant flow path 60 in which a coolant for cooling the power module 20 flows. The flow path casing 40 is an example of the flow path defining member disclosed herein.

The flow path casing 40 includes a plastic material. In this embodiment, the flow path casing 40 is constituted solely of a plastic material.

The flow path casing 40 may be constituted solely of, but not particularly limited to, one type of or two or more types of plastic materials. The flow path casing 40 may be constituted of a composite material of one type of or two or more types of plastic materials and other material(s), such as one type of two or more types of materials selected from inorganic materials including metallic materials, ceramic materials, and the like. When the flow path casing 40 is a composite material, the plastic-based matrix may include inorganic dispersions, such as carbon fibers and glass fibers derived from a metallic and/or ceramic material as dispersions. Further, the metallic matrix may include dispersants derived from ceramic or plastic. The dispersants may be in various known forms, such as fibers, particles, or the like.

The plastic material is not particularly limited, and any known material can be used as appropriate. For example, a plastic material generally has lower thermal conductivity than a metal material. Therefore, when focusing on thermal conductivity, it is advantageous in some cases to use a known plastic with excellent thermal conductivity. For example, a polycarbonate resin, a polybutylene terephthalate resin, a polyacetal resin, a modified polyphenylene ether resin, and a polyamide resin, which all are modified to have high thermal conductivity, can be used.

The metallic and ceramic materials are not particularly limited, and any known material may be used as appropriate. The metallic and ceramic materials may be blended in various forms for various purposes with the plastic material(s) forming the matrix. The metallic material(s) may form the matrix and the metallic and ceramic materials may be blended in various forms to reduce weight.

The flow path casing 40 needs only have a shape that can define the coolant flow path 60 together with the heat sink 30. For example, as illustrated in FIGS. 2 and 4, when the heat sink 30 has a plate shape, the flow path casing 40 can include a substantially cylindrical sidewall 42 that surrounds the heat sink 30 along the outer edge 36 of the heat sink 30. The plate 32 of the heat sink 30 and the sidewall 42 of the flow path casing 40 can define a recess 38 defined by the heat sink 30 and the sidewall 42. The coolant flow path 60 can be easily formed in this recess 38. The sidewall 42 is an example of the sidewall portion disclosed herein.

As shown in FIGS. 2 and 4, when the flow path casing 40 includes the sidewall 42, a cover 80 to close an opening enclosed by the sidewall 42 of the flow path casing 40 can be included. The cover 80 can include, for example, a plastic material as well as the flow path casing 40. The cover 80 is fixed to the flow path casing 40 or the unit casing 10a. The cover 80 is an example of the cover member disclosed herein.

When the heat sink 30 has a plate shape, the flow path casing 40 can also include the substantially cylindrical sidewall 42 surrounding the heat sink 30 along the outer edge 36 of the heat sink 30 and a bottom portion continuous from this sidewall. The surface 32b of the plate 32 of the heat sink 30 and the sidewall 42 and the bottom portion of the flow path casing 40 can define the coolant flow path 60 in the interior space thereof.

Further, for example, when the heat sink 30 has the plate 32 as its apex and the entire end 36a of the heat sink 30 extending a predetermined length toward one side in a vehicle width direction, for example, it may have a container-like shape opening toward the one side in the vehicle width direction. In such a case, the flow path casing 40 can include a plate that closes the aforementioned opening or in a form of a recess with an opening corresponding to the afore-mentioned opening. In these cases as well, the plate 32 of the heat sink 30 and the flow path casing 40 can still define the coolant flow path 60.

A manner in which the flow path casing 40 is integrated into the heat sink 30 is not particularly limited, but as shown in FIG. 4, for example, the flow path casing 40 is integrated so as to hold the end 36a in directions along the thickness of an outermost protruding end 36a of the outer edge 36 of the heat sink 30. By configuring as such, the integrity of the heat sink 30 and the flow path casing 40 is increased, by which the liquid-tightness against the coolant is also increased and an area at which they are in contact is increased and they are firmly integrated. The end 36a of the heat sink 30 is not particularly limited, and it only needs to secure a necessary area at which they are in contact and enable integration with the flow path casing 40.

In integrating the heat sink 30 being metal and the flow path casing 40 being plastic, various known joining methods can be used. For example, in the present embodiment, the integration is performed by insert molding using plastic injection molding.

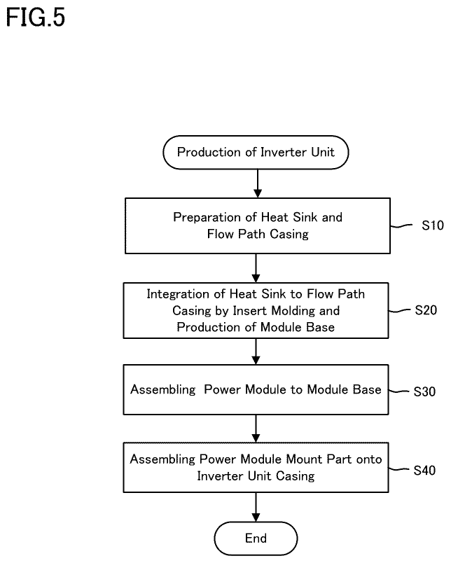

An example of a production process of the inverter unit 10 using insert molding is illustrated in FIG. 5. As shown in FIG. 5, first, the heat sink 30 and the flow path casing 40 are separately prepared (step S10). Next, the heat sink 30 is used as an insert and a plastic material used as a material for the flow path casing 40 is injected into a mold, by which the heat sink 30 and the flow path casing 40 are integrated to produce a module base on which the power module 20 is assembled (step S20). The power module 20 is assembled to the plate 32 included in this module base (Step S30). By configuring as such, a power module mount part of the inverter unit 10 is produced. Furthermore, the inverter unit 10 can be obtained by assembling this power module mount part onto the unit casing 10a (step S40). The module base is an example of the assembly base of the power module disclosed herein.

The integration of the heat sink 30 and the flow path casing 40 is not limited to insert molding, but various known joining methods can be employed. For example, in addition to direct integration by such molding, there are integration by an adhesive, integration by melting of plastic and anchoring effects of plastic to a metal surface, and integration by surface treatment on either or both the heat sink 30 and the flow path casing 40, and an adhesive. These integration methods can be selected and combined according to, for example, materials of the heat sink 30 and the flow path casing 40.

By installing a coolant inlet and a coolant outlet in the coolant flow path 60 of the inverter unit 10 of the drive device 100 produced as above, the coolant can flow in the coolant flow path 60.

The drive device 100 of the present embodiment includes the coolant flow path 60 defined by combining the heat sink 30 and the flow path casing 40 integrated into the heat sink 30. This promotes further weight reduction of the inverter unit 10 and the drive device 100.

In the drive device 100 of the present embodiment, the inverter unit 10 is arranged adjacent to the gear unit 16 and the like, along the vehicle width direction. Therefore, the weight reduction of the drive device 100 and the presence of the plastic material can attenuate or dampen vibrations and the like of the drive device 100. For example, this is effective when force is applied, such as in acceleration and deceleration in a vehicle.

Further, it may be advantageous for the coolant flow path 60 to be formed of a composite of metal and plastic materials. In other words, since the only object to be cooled by the coolant that flowed into the coolant flow path 60 is the heat sink 30, it may be advantageous for the parts other than the heat sink 30 to be made of a plastic material and have generally low thermal conductivity, since heat dissipation to the outside is suppressed and insulation from the outside is provided.

In the above explanation, the unit casing 10a of the inverter unit 10 is constituted of metal, however, for example, the unit casing 10a may include a plastic material. By configuring as such, for example, further weight reduction can be achieved. In the above explanation, the drive device 100 is provided by arranging the inverter unit 10 and the like side by side along the width directions of the vehicle 2, however, the configuration is not limited to this and the drive device 100 may include these components in up-down directions of the vehicle 2.

The vehicle 2 comprising the drive device 100 is also an embodiment of the disclosure herein. The module base and the power module mount part described in the production process of the inverter unit 10 are both useful as parts of the power converter disclosed herein, and are one embodiment of the disclosure herein.

The present disclosure includes the following configurations:
[1] A power converter, comprising;
   a power module comprising at least one power semiconductor element;
   a metal plate being in thermal connection with the at least one power semiconductor element, and
   a flow path defining member including a plastic material and defining a coolant flow path together with the metal plate,
   wherein a coolant flows through the coolant flow path, and
   the flow path defining member is integrated into the metal plate.
[2] The power converter according to [1], wherein the flow path defining member is integrated into the metal plate by holding an end of an outer edge of the metal plate.
[3] The power converter according to [1] or [2], wherein the flow path defining member is integrated into the metal plate by insert molding.
[4] The power converter according to any of [1] to [3], wherein the flow path defining member comprises a sidewall portion surrounding the metal plate along the outer edge of the metal plate and defining a recess defined by the metal plate and the sidewall portion.
[5] The power converter according to [4], further comprising a cover member including a plastic material closing an opening of the recess.
[6] A method of producing a power converter comprising a power module, the method comprising:
   preparing an assembly base of the power module by integrally molding a flow path defining member including a plastic material into a metal plate to be thermally connected with the power module, the flow path defining member defining a coolant flow path for a coolant together with the metal plate, and
   assembling the power module into the assembly base.
[7] A drive device, comprising:
   the power converter according to [1] to [5], and
   a motor configured to be driven by power supplied through the power converter.
[8] The drive device according to [7], wherein the drive device is configured to drive a vehicle wheel.
[9] A vehicle comprising the drive device of [7].
[10] A component of a power converter, comprising;
   a metal plate being in thermal connection with at least one power semiconductor element, and
   a flow path defining member including a plastic material and defining a coolant flow path together with the metal plate, a coolant flows through the coolant flow path,
   wherein the flow path defining member is integrated into the metal plate.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. A power converter comprising;
a power module comprising at least one power semiconductor element;
a metal plate being in thermal connection with the at least one power semiconductor element, and
a flow path defining member including a plastic material and defining a coolant flow path together with the metal plate,
wherein a coolant flows through the coolant flow path, and
the flow path defining member is integrated into the metal plate.

2. The power converter according to claim 1, wherein the flow path defining member is integrated into the metal plate by holding an end of an outer edge of the metal plate.

3. The power converter according to claim 2, wherein the flow path defining member is integrated into the metal plate by insert molding.

4. The power converter according to claim 3, wherein the flow path defining member comprises a sidewall portion surrounding the metal plate along the outer edge of the metal plate and defining a recess defined by the metal plate and the sidewall portion.

5. The power converter according to claim 4, further comprising a cover member including a plastic material and closing an opening of the recess.

6. A method of producing a power converter comprising a power module, the method comprising:
preparing an assembly base of the power module by integrally molding a flow path defining member including a plastic material into a metal plate to be thermally connected with the power module, the flow path defining member defining a coolant flow path for a coolant together with the metal plate, and
assembling the power module into the assembly base.

7. A drive device, comprising:
the power converter according to claim 1, and
a motor configured to be driven by power supplied through the power converter.

8. The drive device according to claim 7, wherein the drive device is configured to drive a vehicle wheel.
